(19) United States
(12) Patent Application Publication
(10) Pub. No.: US 2025/0266746 A1
(43) Pub. Date: Aug. 21, 2025

(54) Two-Phase Smart Power Stage (SPS) for Multiphase Buck Converters

(71) Applicant: Reed Semiconductor Corporation, Warwick, RI (US)

(72) Inventors: Wenkai Wu, East Greenwich, RI (US); Weidong Zhu, East Lyme, CT (US); Qian Chen, Cary, NC (US); Jialun Du, Powell, OH (US); Cheng-Wei Chen, East Greenwich, RI (US)

(21) Appl. No.: 19/203,684

(22) Filed: May 9, 2025

Related U.S. Application Data
(63) Continuation-in-part of application No. 17/983,703, filed on Nov. 9, 2022, now Pat. No. 12,301,115.
(60) Provisional application No. 63/287,905, filed on Dec. 9, 2021.

(51) Int. Cl. H02M 1/00; G01R 19/00; H02M 3/156

(52) U.S. Cl. CPC H02M 1/0009; G01R 19/0092; H02M 3/156

(57) ABSTRACT

An apparatus includes a second phase PWM off time current sense circuit configured to generate a second phase PWM off time current signal proportional to a current flowing through a second inductor when a high-side switch of the second phase is turned off and a low-side switch of the second phase is turned on, a second phase PWM on time current rebuild circuit configured to construct an artificial second phase inductor current signal using a second phase voltage-controlled current source to charge a second rebuild capacitor when the high-side switch of the second phase is turned on, and a second phase feedback loop configured to adjust a current flowing through the second phase voltage-controlled current source so as to force a saved voltage of the artificial second phase inductor current signal to be equal to a saved voltage of the second phase PWM off time current signal.

### PRIORITY

This application is a continuation in part application of U.S. patent application Ser. No. 17/983,703, entitled “Two-Phase Smart Power Stage (SPS) for Multiphase Buck Converters” and filed on Nov. 9, 2022, which claims the benefit of U.S. Provisional Application No. 63/287,905, filed on Dec. 9, 2021, which is hereby incorporated herein by reference.

### TECHNICAL FIELD

The present invention relates to a smart power stage for multiphase DC/DC converters, and more particularly, the present invention relates to a smart power stage for multi-phase buck converters.

### BACKGROUND

DC/DC converters are known in the art to step-up and step-down DC voltage. The step-down converters are commonly referred to as Buck converters. The buck converters belong to a class of switched-mode power supply (SMPS) that contains transistors, inductors, and capacitors. A buck converter uses a transistor as a switch that alternately connects and disconnects the input voltage to an inductor. The time for which a switch is ON divided by the total duration is referred to as the duty cycle. A basic buck converter topology has a transistor and a diode. The diode can be replaced by the second transistor in synchronous buck converters. MOSFETS have been used in place of transistors because of their higher efficiency. Also, pulse width modulation (PWM) is generally used to set the switch ON time based on a feedback loop. The output voltage can be directly regulated by changing the switch ON time.

A single-phase buck converter is suitable for low voltage converter applications for limited current capacity. Higher current capacity requires large component sizes and better heat dissipation because of a large amount of heat generated. One approach to handle large current capacities is to use a multiphase buck converter. The multiphase buck converter has two or more buck converters connected in parallel and the phases are interleaved. The multi-phase buck converter has several advantages, such as reducing ripple currents, hotspots, decreasing output filter requirements, improved Load-transient performance, and many others. However, the multiphase buck converters suffer from one major drawback of switching loss which can become significant in the majority of the applications.

There currently exists an industry need for an improved circuit topology for multiphase buck converters that have lower switching losses and all the advantages of the multiphase buck converters.

### SUMMARY

The principal object of the present invention is therefore directed to a two-phase smart power stage for multi-phase step-down DC-DC converter that overcomes the aforesaid drawback of multi-phase buck converters by having lower switching losses.

It is another object of the present invention that the switching stress on each switch can be reduced by half.

It is still another object of the present invention that the inductor current ripple, and thus the output voltage ripple can be reduced.

It is yet another object of the present invention to enable the use of low voltage rating devices for low side MOSFETs with the improved figure of merit and thus further improve the efficiency.

It is a further object of the present invention to further miniaturize the multi-phase DC-DC converters.

It is still a further object of the present invention to shield the output load against damage caused by high side FET failure.

It is an additional object of the present invention that the current in the circuit can be automatically balanced.

In one aspect, disclosed is a two-phase smart power stage for multi-phase step-down DC-DC converter, wherein in a typical multi-phase step-down DC-DC converter comprises a first two-phase smart power stage, the first two-phase smart power stage comprises a first high side switch, a second high side switch, a first low side switch, a second low side switch, a first switching capacitor, a first inductor, and a second inductor; and a second two-phase smart power stage, the second two-phase smart power stage comprises a third high side switch, a fourth high side switch, a third low side switch, a fourth low side switch, a second switching capacitor, a third inductor, and a fourth inductor. A first leg of the first high side switch and a first leg of the third high side switch are electrically connected to a first terminal, a second leg of the first high side switch, a first leg of the first switching capacitor, and a first leg of the second high side switch are electrically connected to a second terminal, a second leg of the first switching capacitor, a first leg of the first low side switch, and a first leg of the first inductor are electrically connected to a third terminal, a second leg of the first inductor is electrically connected to a fourth terminal, a second leg of the second high side switch, a first leg of the second low side switch, and a first leg of the second inductor are electrically connected to a fifth terminal, a second leg of the second inductor is electrically connected to the fourth terminal, a second leg of the third high side switch, a first leg of the second switching capacitor, and a first leg of the fourth high side switch are electrically connected to a sixth terminal, a second leg of the second switching capacitor, a first leg of the third low side switch, and a first leg of the third inductor are electrically connected to a seventh terminal, a second leg of the third inductor is electrically connected to the fourth terminal, a second leg of the fourth high side switch, a first leg of the fourth low side switch, and a first leg of the fourth inductor are electrically connected to an eight terminal, and a second leg of the fourth inductor is electrically connected to the fourth terminal. The first terminal is further electrically connected to a voltage input source. The fourth terminal is further electrically connected to a capacitor and a load. The first high side switch, the second high side switch, the first low side switch, the second low side switch, the third high side switch, the fourth high side switch, the third low side switch, the fourth low side switch are MOSFETs. The multi-phase step-down DC-DC converter further comprises a multiphase controller, wherein the multiphase controller is configured to generate an interleaved first phase pulse-duration modulation signal for the first two-phase smart power stage and second phase pulse-duration modulation signal for the second two-phase smart power stage.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

The accompanying figures, which are incorporated herein, form part of the specification and illustrate embodiments of the present invention. Together with the description, the figures further explain the principles of the present invention and to enable a person skilled in the relevant arts to make and use the invention.

FIG. 1 is a circuit diagram showing a four-phase multi-phase step-down DC-DC converter adopting the two-phase smart power stages, according to an exemplary embodiment of the present invention;

FIG. 2 shows the PWM and switch node Waveforms for the multi-phase step-down DC-DC converter, according to an exemplary embodiment of the present invention;

FIG. 3 shows the waveform of the PWM distribution circuit, according to an exemplary embodiment of the present invention;

FIG. 4 is a block diagram of the two-phase smart power stage, according to an exemplary embodiment of the present invention;

FIG. 5 illustrates a schematic diagram of a power converter and a block diagram of a first current sense apparatus for sensing a current flowing through an inductor of a first phase of the power converter and a second current sense apparatus for sensing a current flowing through an inductor of a second phase of the power converter in accordance with various embodiments of the present disclosure;

FIG. 6 illustrates various control signals associated with the first current sense apparatus and the second current sense apparatus shown in FIG. 5 in accordance with various embodiments of the present disclosure;

FIG. 7 illustrates a schematic diagram of the first current sense apparatus shown in FIG. 5 in accordance with various embodiments of the present disclosure;

FIG. 8 illustrates a schematic diagram of the low side current sense unit shown in FIG. 7 in accordance with various embodiments of the present disclosure;

FIG. 9 illustrates various control signals associated with the first current sense apparatus and the second current sense apparatus shown in FIG. 5 in accordance with various embodiments of the present disclosure;

FIG. 10 illustrates a schematic diagram of the second current sense apparatus shown in FIG. 5 in accordance with various embodiments of the present disclosure; and

FIG. 11 illustrates a flow chart of a method for sensing the currents flowing through the power converter shown in FIG. 5 in accordance with various embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

Subject matter will now be described more fully hereinafter with reference to the accompanying drawings, which form a part hereof, and which show, by way of illustration, specific exemplary embodiments. Subject matter may, however, be embodied in a variety of different forms and, therefore, covered or claimed subject matter is intended to be construed as not being limited to any exemplary embodiments set forth herein; exemplary embodiments are provided merely to be illustrative. Likewise, a reasonably broad scope for claimed or covered subject matter is intended. Among other things, for example, the subject matter may be embodied as methods, devices, components, or systems. The following detailed description is, therefore, not intended to be taken in a limiting sense.

The word “exemplary” is used herein to mean “serving as an example, instance, or illustration.” Any embodiment described herein as “exemplary” is not necessarily to be construed as preferred or advantageous over other embodiments. Likewise, the term “embodiments of the present invention” does not require that all embodiments of the invention include the discussed feature, advantage, or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

The following detailed description includes the best currently contemplated mode or modes of carrying out exemplary embodiments of the invention. The description is not to be taken in a limiting sense but is made merely for the purpose of illustrating the general principles of the invention, since the scope of the invention will be best defined by the allowed claims of any resulting patent.

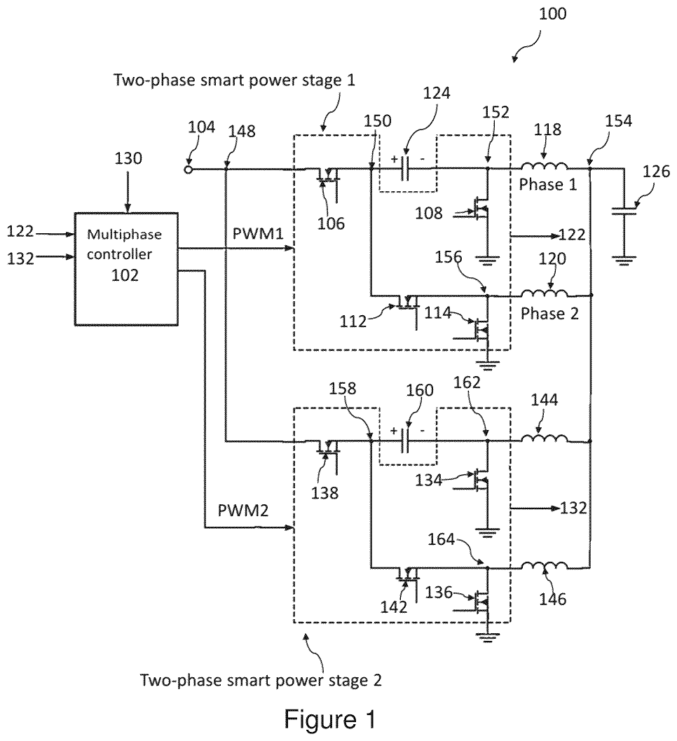

Disclosed is a two-phase smart power stage for multi-phase step-down DC-DC converter that can be used in high current applications, such as power supplies for processors, FPGA, ASIC, etc. Referring to FIG. 1 which is a circuit diagram for an exemplary embodiment of a multi-phase step-down DC-DC converter 100 comprising the disclosed two-phase smart power stages. The circuit diagram in FIG. 1 shows two two-phase smart power stages i.e., smart power stage 1 and smart power stage 2, wherein each smart power stage has two phases. The two smart power stages are shown connected to a common voltage input (VIN) 104. Also, both the smart power stages can be seen connected to a multiphase controller 102. The multiphase controller 102 can send the PWM signals to the two smart power stages. Each smart power stage includes a transistor as a first high side switch. The first high side switch can preferably be a MOSFET. Each smart power stage can also include a first low side switch which can also preferably be a MOSFET. Each smart power stage can also include a switching capacitor electrically coupled to the first high side switch and the first low side switch. Each smart power stage can also include a second high side switch and a second low side switch. Each smart power stage can also connect to a first inductor and a second inductor for the two phases respectively.

The multi-phase step-down DC-DC converter has a voltage input 104, a first high side switch 106 of smart power stage 1, and a first high side switch 138 of smart power stage 2 all electrically connected to a first terminal 148. A second leg of the first high side switch 106, a first leg of a first switching capacitor 124, and a first leg of a second high side switch 112 can be electrically connected to a second terminal 150. The first low side switch 108, the second leg of the first switching capacitor 124, and the first inductor 118 are also electrically connected to the third terminal 152. The opposite terminal of the first inductor 118 can also be connected to a fourth terminal 154. The second high side switch 112 and the second low side switch 114 can be connected to a fifth terminal 156. The second inductor 120 at one end can be connected to the fifth terminal 156 and another end of the second inductor 120 can be connected to the fourth terminal 154. The capacitor 126 can be connected to the fourth terminal 154. The fourth terminal 154 can be connected to the load and has a voltage output.

Referring to the second smart power stage of the multi-phase step-down DC-DC converter 100 shown in FIG. 1, the third high side switch 138 and the second switching capacitor 160 can be connected to a sixth terminal 158. The other end of the second switching capacitor 160 and the third low side switch 134 can be connected to a seventh terminal 162. The third inductor 144 can at one terminal be connected to the seventh terminal 162 while the other terminal of the third inductor 144 can be connected to the fourth terminal 154. Fourth high side switch 142 at one end can be connected to the sixth terminal 158 and another end of the fourth high side switch 142 can be connected to an eighth terminal 164. Similarly, a fourth low side switch 136 at one end can be connected to the eighth terminal 164 and another end of the fourth low side switch 136 can be ground. A fourth inductor 146 at one end can be connected to the eighth terminal 164 and another end of the fourth inductor 146 can be connected to the fourth terminal 154. The second smart power stage or any further stages can have the same topology as described above for the first smart power stage and all the smart power stages can be connected to the voltage input 104 and the voltage output 154.

The first switching capacitor 124 is inserted between the first high side switch 106 and the first low side switch 108, and the drain of the second high side switch 112 is connected to the source of the first high side switch 106, to reduce the voltage during switching, resulting in reduced power loss and improved efficiency. The switches can be operated by a gate driver circuit which can receive control signals from the multiphase controller 102. The multiphase controller 102 can send a single PWM signal to each smart power stage and accordingly the MOSFETs can be turned on/off to convert the input voltage to a lower output voltage Vout. Each smart power stage can receive the PWM signal from the multiphase controller and distribute it to the two phases of the smart power stage sequentially. The multi-phase controller can receive the Vout feedback 130 and determine the duty cycle of PWM. The current flowing through the circuit can be sensed by a current sense integration circuit (not shown), the current sense integration circuit can sense the current of each phase of the two phases of the smart power stage and sum it up and then send the combined signal to the multi-phase controller. This current signal can be used for control, monitoring, or protection purposes. FIG. 1 shows the first combined signal 122 from smart power stage 1 and the second combined signal 132 from smart power stage 2.

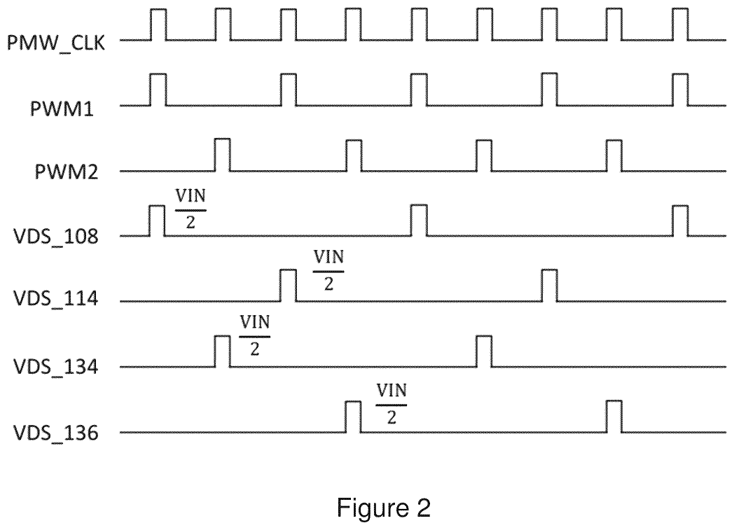

In operation, the first high side switch 106 can be turned on for a predefined duration based on the PWM signal, and the inductor and the capacitor can be charged in the predefined duration. The voltage across the switching capacitor 124 can be half of the Voltage input. The switch node voltages are shown in FIG. 2. Then the first high side switch 106 can be turned off and the second high side switch 112 can be turned on. Now the capacitor can act as the voltage input for the second high side switch 112.

Referring to FIG. 2 which shows the waveform during steady-state operation. The multi-phase controller sends PWM signals to both the smart power stages shown as PWM1 and PWM2. PWM1 is sent to the first smart power stage, which includes two phases, and PWM2 is sent to the second smart power stage which also includes two phases. Using the smart power stage that receives the PWM signal (PWM1 or PWM2) from the multi-phase controller, it processes the PWM signal, and sends the 1st PWM signal to phase 1, and sends the 2nd PWM signal to phase 2. In a steady-state operation, these two phases are 180-degree interleaved. When phase 1 receives the PWM high signal, it turns on the first high side switch 106 and turns off the first low side switch 108. When the PWM signal goes low, the first high side switch 106 is turned off and the first low side switch 108 is turned on. When phase 2 receives the PWM high signal, the second high side switch 112 is turned on, and the second low side switch 114 is turned off. When the PWM signal goes low, the second high side switch is turned off, and the second low side switch is turned on.

During steady-state operation, the voltage across the switching capacitors is about half of the input voltage VIN. At the moment 106 turns on, the voltage across VDS of 106 is VIN/2 since the voltage at the negative terminal of 124 is close to zero. It can also be derived that the voltage across 112 during switching is also VIN/2, since the positive terminal of 124 is VIN/2 and the drain voltage of 114 is close to zero. Therefore, the switching loss is reduced for both the switches i.e., 106 and 112, because of the reduced voltage stress during switching.

The first low side switch 108 and the second low side switch 114 experience zero voltage switching, same as prior art. However, since the maximum voltage experienced by the first low side switch 108 and the second low side switch 114 is VIN/2 instead of VIN as in the prior art, the first low side switch 108 and the second low side switch 114 can be designed with reduced breakdown voltage with lower on-resistance (Rdson) with the same silicon size to further improve efficiency. Also, the Coss loss is reduced because of reduced VIN (Coss loss=½×f_{sw}×Coss×VIN²). FIG. 2 shows the reduced switch node voltages at the switches 108, 114, 134, and 136 shown in FIG. 1.

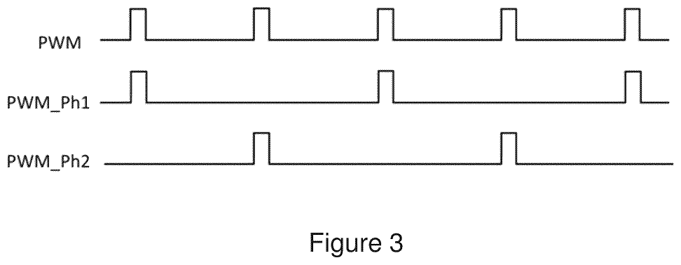

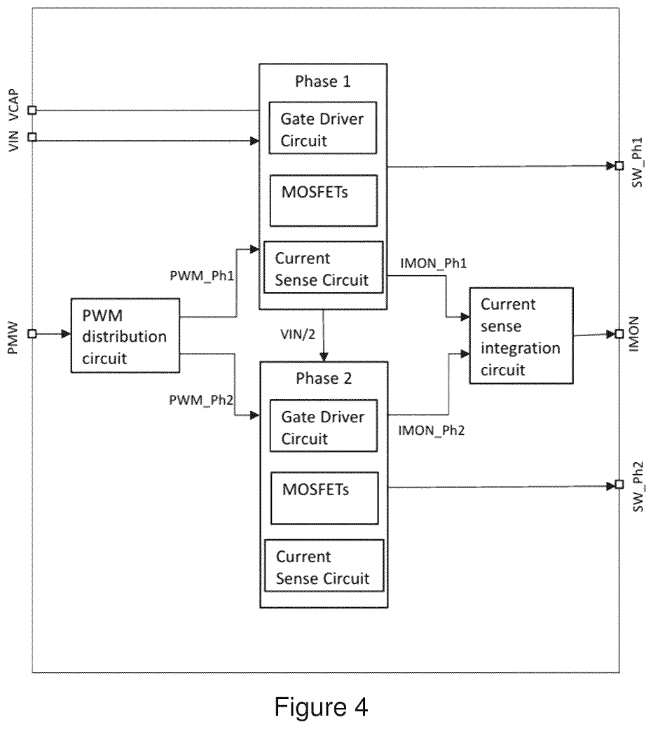

FIG. 3 shows the waveform of the PWM distribution circuit. The two-phase smart power stage comprises of the two phases, each phase has its own gate drive circuit, current sense circuit and MOSFETs. Besides this, the switching capacitor circuit divides the input voltage in half for each of the switching elements (MOSFETs). The PWM distribution circuit receives the PWM signal from the controller and distributes it to the two phases inside the smart power stage sequentially. The current sense integration circuit receives the current sense signals from each phase and integrates them to a summed current signal and sends them to the multi-phase controller. FIG. 4 is a block diagram which illustrates an exemplary embodiment of the disclosed two-phase smart power stage.

Referring back to FIG. 2, leading edges of two consecutive pulses of a drain-to-source voltage (VDS_108) of the first low side switch (108) are aligned with leading edges of a first pulse and a third pulse of the first pulse width modulation signal (PWM1), respectively. Leading edges of two consecutive pulses of a drain-to-source voltage (VDS_114) of the second low side switch (114) are aligned with leading edges of a second pulse and a fourth pulse of the first pulse width modulation signal (PWM1), respectively. As shown in FIG. 2, the first pulse, the second pulse, the third pulse and the fourth pulse of the first pulse width modulation signal (PWM1) are four consecutive pulses.

Referring back to FIG. 2, leading edges of two consecutive pulses of a drain-to-source voltage (VDS_134) of the third low side switch (134) are aligned with leading edges of a first pulse and a third pulse of the second pulse width modulation signal (PWM2), respectively. Leading edges of two consecutive pulses of a drain-to-source voltage (VDS_136) of the fourth low side switch (136) are aligned with leading edges of a second pulse and a fourth pulse of the second pulse width modulation signal (PWM2), respectively. As shown in FIG. 2, the first pulse, the second pulse, the third pulse and the fourth pulse of the second pulse width modulation signal (PWM2) are four consecutive pulses.

As shown in FIG. 2, the switching frequency of the first phase (VDS_108) is lower than the frequency of the first pulse width modulation signal (PWM1). More specifically, the frequency of the first pulse width modulation signal (PWM1) in the present application is twice the switching frequency of the first phase (VDS_108).

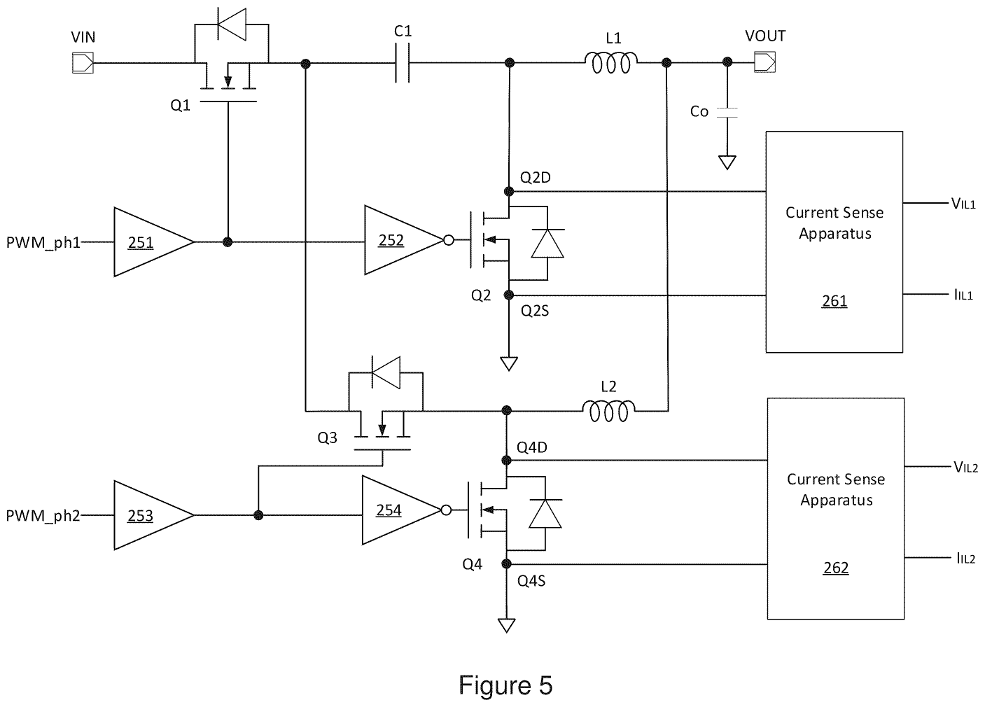

FIG. 5 illustrates a schematic diagram of a power converter and a block diagram of a first current sense apparatus for sensing a current flowing through an inductor of a first phase of the power converter and a second current sense apparatus for sensing a current flowing through an inductor of a second phase of the power converter in accordance with various embodiments of the present disclosure. As shown in FIG. 5, the first phase of the power converter comprises a high-side switch Q1, a low-side switch Q2, a capacitor C1 and a first inductor L1. The high-side switch Q1 of the first phase, the capacitor C1 and the first inductor L1 are connected in series between an input voltage bus VIN and an output voltage bus VOUT. The low-side switch Q2 of the first phase is connected between a common node of the capacitor C1 and the first inductor L1, and ground.

The second phase of the power converter comprises a high-side switch Q3, a low-side switch Q4 and a second inductor L2. The high-side switch Q3 of the second phase and the second inductor L2 are connected in series between a common node of the high-side switch Q1 of the first phase and the capacitor C1, and the output voltage bus VOUT. The low-side switch Q4 of the second phase is connected between a common node of the high-side switch Q3 of the second phase and the second inductor L2, and ground. An output capacitor Co is connected between the output voltage bus VOUT and ground. A load (not shown) is connected in parallel with the output capacitor Co.

In accordance with an embodiment, the switches (eg., switches Q1-Q4) may be metal oxide semiconductor field-effect transistor (MOSFET) devices. Alternatively, the switches can be any controllable switches such as insulated gate bipolar transistor (IGBT) devices, integrated gate commutated thyristor (IGCT) devices, gate turn-off thyristor (GTO) devices, silicon-controlled rectifier (SCR) devices, junction gate field-effect transistor (JFET) devices, MOS controlled thyristor (MCT) devices, gallium nitride (GaN)-based power devices, silicon carbide (SiC)-based power devices and the like.

It should be noted while FIG. 5 shows the switches Q1 and Q3 are implemented as single n-type transistors, a person skilled in the art would recognize there may be many variations, modifications and alternatives. For example, depending on different applications and design needs, the switches Q1 and Q3 may be implemented as p-type transistors. Furthermore, each switch shown in FIG. 5 may be implemented as a plurality of switches connected in parallel.

The power converter further comprises a first high-side driver 251, a second high-side driver 253, a first inverter 252 and a second inverter 254. In some embodiments, the first inverter 252 functions as a first low-side driver. The second inverter 254 functions as a second low-side driver.

The first high-side driver 251 is configured to receive the PWM signal PWM_ph1. PWM_ph1 corresponds to the gate drive signal applied to the switch 106 shown in FIGS. 1-2 (i.e., the odd pulses of PWM1). Based on the received signal, the first high-side driver 251 generates a high-side gate drive signal applied to the gate of the high-side switch Q1. Furthermore, the PWM signal PWM_ph1 passes through the first inverter 252. Based on the received signal, the first inverter 252 generates a low-side gate drive signal applied to the gate of the low-side switch Q2.

The second high-side driver 253 is configured to receive the PWM signal PWM_ph2. PWM_ph2 corresponds to the gate drive signal applied to the switch 114 shown in FIGS. 1-2 (i.e., the even pulses of PWM1). Based on the received signal, the second high-side driver 253 generates a high-side gate drive signal applied to the gate of the high-side switch Q3. Furthermore, the PWM signal PWM_ph2 passes through the second inverter 254. Based on the received signal, the second inverter 254 generates a low-side gate drive signal applied to the gate of the low-side switch Q4.

The driver circuit shown in FIG. 5 is a simplified representation provided to illustrate the innovative aspects of the present disclosure. It should be understood that in practical implementations, the driver circuit may include additional functional blocks such as a dead time control circuit or other necessary circuitry to ensure proper operation.

The power converter further comprises a first current sense apparatus 261 and a second current sense apparatus 262. As shown in FIG. 5, a first input of the first current sense apparatus 261 is connected to a drain Q2D of the low-side switch Q2. A second input of the first current sense apparatus 261 is connected to a source Q2S of the low-side switch Q2. The first current sense apparatus 261 is configured to sense the current flowing through the first inductor L1. As shown in FIG. 5, the first current sense apparatus 261 is configured to generate a voltage signal V_{IL1} and a current signal I_{IL1}. Both signals are proportional to the current flowing through the first inductor L1. Throughout the description, V_{IL1} is alternatively referred to as a first inductor current detection signal V_{IL1}.

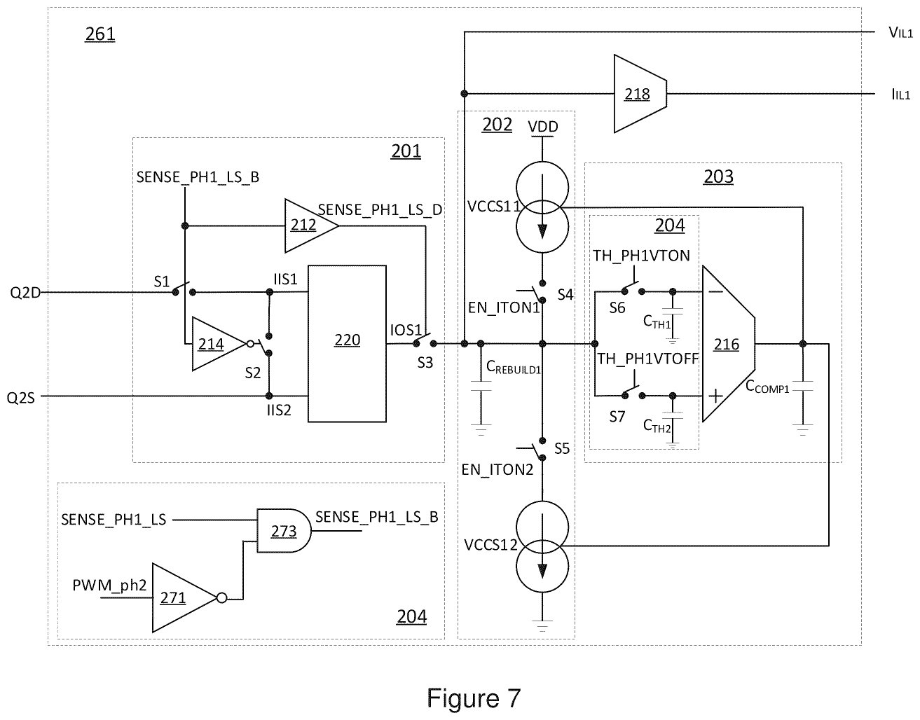

In some embodiments, the first current sense apparatus 261 comprises a first phase PWM off time current sense circuit, a first phase PWM on and off time current rebuild circuit and a first phase feedback loop. The detailed structure and operating principle of the first current sense apparatus 261 will be described below with respect to FIG. 7.

As shown in FIG. 5, a first input of the second current sense apparatus 262 is connected to a drain Q4D of the low-side switch Q4. A second input of the second current sense apparatus 262 is connected to a source Q4S of the low-side switch Q4. The second current sense apparatus 262 is configured to sense the current flowing through the second inductor L2. As shown in FIG. 5, the second current sense apparatus 262 is configured to generate a voltage signal V_{IL2} and a current signal I_{IL2}. Both signals are proportional to the current flowing through the second inductor L2. Throughout the description, V_{IL2} is alternatively referred to as a second inductor current detection signal V_{IL2}.

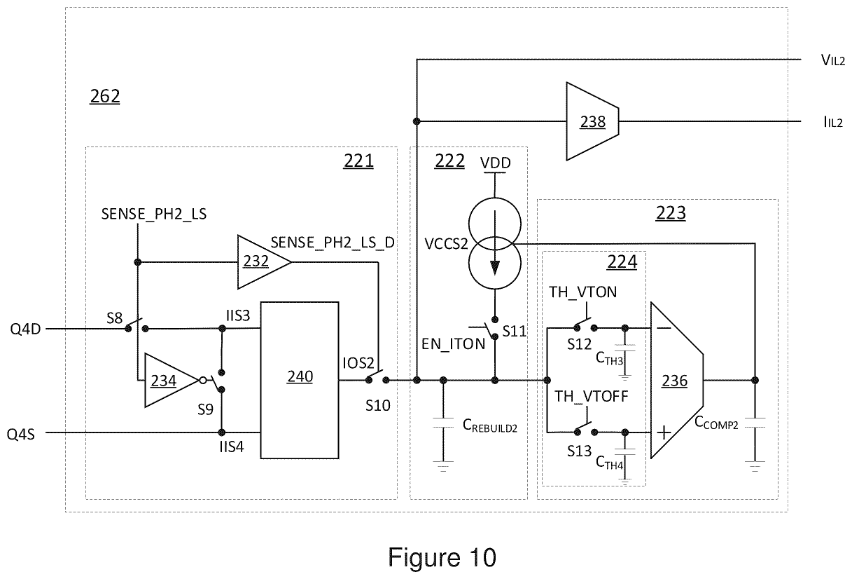

In some embodiments, the second current sense apparatus 262 comprises a second phase PWM off time current sense circuit, a second phase PWM on time current rebuild circuit and a second phase feedback loop. The detailed structure and operating principle of the second current sense apparatus 262 will be described below with respect to FIG. 10.

In operation, the first phase PWM off time current sense circuit is configured to generate a first portion and a third portion of a first phase PWM off time current signal proportional to the current flowing through a first inductor L1 when the high-side switch Q1 is turned off, the high-side switch Q3 is turned off, and the low-side switch Q2 is turned on.

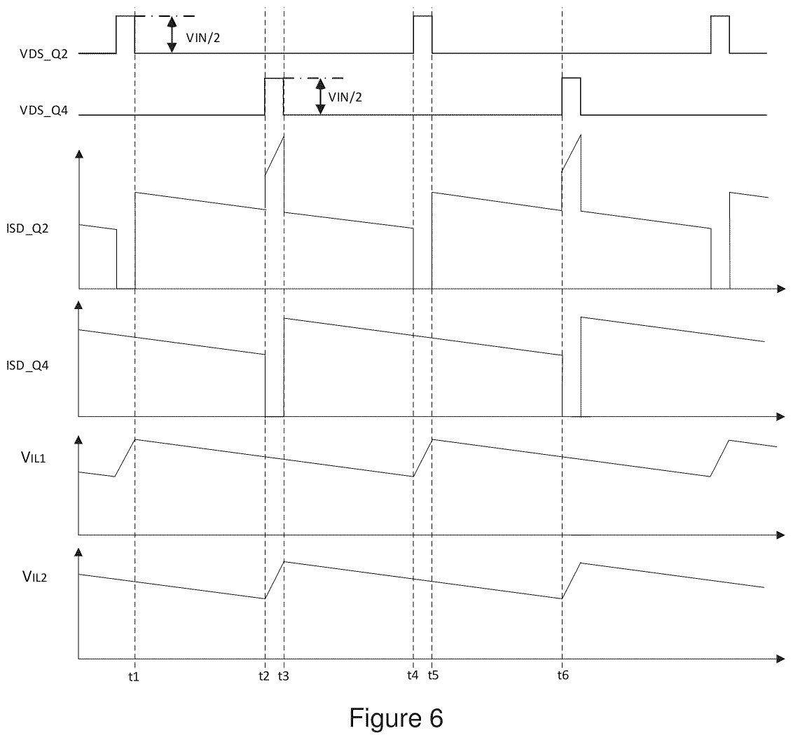

In operation, the first phase PWM on and off time current rebuild circuit is configured to construct a second portion of the first phase PWM off time current signal using a second voltage-controlled current source to discharge a first rebuild capacitor when the high-side switch Q3 of the second phase is turned on. Furthermore, the first phase PWM on and off time current rebuild circuit is configured to construct an artificial first phase inductor current signal using a first voltage-controlled current source to charge the first rebuild capacitor when a high-side switch Q1 of the first phase is turned on. The detailed current sense signal of the first phase will be discussed below with respect to FIG. 6.

In operation, the first phase feedback loop is configured to adjust the current flowing through the second voltage-controlled current source so as to force a saved voltage of the second portion of the first phase PWM off time current signal to be equal to a saved voltage of the third portion of the first phase PWM off time current signal. Furthermore, the first phase feedback loop is configured to adjust a current flowing through the first voltage-controlled current source so as to force a saved voltage of the artificial first phase inductor current signal to be equal to a saved voltage of the first portion of the first phase PWM off time current signal.

In operation, the second phase PWM off time current sense circuit is configured to generate a second phase PWM off time current signal proportional to a current flowing through the second inductor L2 when the high-side switch Q3 of the second phase is turned off and the low-side switch Q4 of the second phase is turned on.

In operation, the second phase PWM on time current rebuild circuit is configured to construct an artificial second phase inductor current signal using a second phase voltage-controlled current source to charge a second rebuild capacitor when the high-side switch Q3 of the second phase is turned on.

In operation, the second phase feedback loop is configured to adjust a current flowing through the second phase voltage-controlled current source so as to force a saved voltage of the artificial second phase inductor current signal to be equal to a saved voltage of the second phase PWM off time current signal.

FIG. 6 illustrates various control signals associated with the first current sense apparatus and the second current sense apparatus shown in FIG. 5 in accordance with various embodiments of the present disclosure. The horizontal axis of FIG. 6 represents intervals of time. There are six rows in FIG. 6. The first row represents the drain-to-source voltage of Q2 (VDS_Q2). The second row represents the drain-to-source voltage of Q4 (VDS_Q4). The third row represents the current flowing through Q2 (ISD_Q2). The fourth row represents the current flowing through Q4 (ISD_Q4). The fifth row represents the first inductor current detection signal V_{IL1} generated by the first current sense apparatus 261. The sixth row represents the second inductor current detection signal V_{IL2} generated by the second current sense apparatus 262.

At t1, the high-side switch Q1 is turned off, and the low-side switch Q2 is turned on. In response to this change, the current flowing through Q2 (ISD_Q2) reduces in a linear manner from t1 to t2. Meanwhile, the low-side switch Q4 remains on. The current flowing through Q4 (ISD_Q4) reduces in a linear manner from t1 to t2.

At t2, the high-side switch Q3 is turned on, and the low-side switch Q4 is turned off. Once Q3 is turned on, the voltage difference between the voltage across the capacitor C1 and the output voltage is applied to the second inductor L2. Both the current flowing through L1 and the current flowing through L2 go through Q2. As a result, from t2 to t3, ISD_Q2 is equal to the sum of the current flowing through L1 and the current flowing through L2.

At t3, the high-side switch Q3 is turned off, and the low-side switch Q4 is turned on. In response to this change, only the current flowing through L1 goes through Q2 (ISD_Q2). From t3 to t4, the current flowing through Q2 (ISD_Q2) reduces in a linear manner. Meanwhile, the low-side switch Q4 is turned on. The current flowing through Q4 (ISD_Q4) reduces in a linear manner from t3 to t4.

At t4, the high-side switch Q1 is turned on, and the low-side switch Q2 is turned off. In response to this change, the current flowing through L1 increases in a linear manner from t4 to t5. Meanwhile, the low-side switch Q4 remains on. The current flowing through Q4 (ISD_Q4) reduces in a linear manner from t4 to t5.

For simplicity, only one period of the first phase is described in detail. The remaining portions of the waveforms repeat in a similar manner.

The current sense signal V_{IL1} is a voltage signal proportional to the current flowing through L1. The current sense signal V_{IL2} is a voltage signal proportional to the current flowing through L2. The segment of V_{IL1} between t1 and t2 corresponds to a first portion of the first phase PWM off time current signal. The segment of V_{IL1} between t2 and t3 corresponds to a second portion of the first phase PWM off time current signal. The segment of V_{IL1} between t3 and t4 corresponds to a third portion of the first phase PWM off time current signal. The segment of V_{IL1} between t4 and t5 corresponds to an artificial first phase inductor current signal. The segment of V_{IL2} between t2 and t3 corresponds to an artificial second phase inductor current signal. The segment of V_{IL2} between t3 and t6 corresponds to a second phase PWM off time current signal.

Referring back to FIG. 5, the first current sense apparatus 261 is configured to generate the voltage signal V_{IL1} based on the current flowing through Q2 (ISD_Q2). As shown in FIG. 6, from t1 to t2 and from t3 to t4, ISD_Q2 comprises the current flowing through L1. From t2 to t3, ISD_Q2 includes the combined currents of both L1 and L2. In order to construct an accurate V_{IL1} as shown in FIG. 6, the first phase PWM off time current sense circuit in the first current sense apparatus 261 is configured to generate the first portion and the third portion of the first phase PWM off time current signal. The first phase PWM on and off time current rebuild circuit in the first current sense apparatus 261 is configured to construct the second portion of the first phase PWM off time current signal using a second voltage-controlled current source to discharge a first rebuild capacitor when the high-side switch Q3 of the second phase is turned on. Furthermore, the first phase PWM on and off time current rebuild circuit is configured to construct an artificial first phase inductor current signal using a first voltage-controlled current source to charge the first rebuild capacitor when a high-side switch Q1 of the first phase is turned on. By concatenating these three portions together, the first inductor current detection signal V_{IL1} can be obtained.

Likewise, the second current sense apparatus 262 is configured to generate the voltage signal V_{IL2} based on the current flowing through Q4 (ISD_Q4). As shown in FIG. 6, from t2 to t3, ISD_Q4 does not include the current flowing through L2. In order to construct an accurate V_{IL2} as shown in FIG. 6, the second phase PWM on time current rebuild circuit is configured to construct an artificial second phase inductor current signal using a second phase voltage-controlled current source to charge a second rebuild capacitor when the high-side switch Q3 of the second phase is turned on. The second phase PWM off time current sense circuit is configured to generate a second phase PWM off time current signal proportional to a current flowing through the second inductor L2 when the high-side switch Q3 of the second phase is turned off and the low-side switch Q4 of the second phase is turned on. By concatenating these two signals together, the second inductor current detection signal V_{IL2} can be obtained.

The detailed implementations of the first phase PWM off time current sense circuit, the first phase PWM on and off time current rebuild circuit, the second phase PWM off time current sense circuit and the second phase PWM on time current rebuild circuit will be discussed below with respect to FIGS. 7-10.

FIG. 7 illustrates a schematic diagram of the first current sense apparatus shown in FIG. 5 in accordance with various embodiments of the present disclosure. The first current sense apparatus 261 comprises a first phase PWM off time current sense circuit 201, a first phase PWM on and off time current rebuild circuit 202, a first phase feedback loop 203 and a blanking circuit 204 as shown in FIG. 7.

The blanking circuit 204 comprises an AND gate 273 and a blanking inverter 271. The input of the blanking inverter 271 is configured to receive PWM_ph2. The first input of the AND gate 273 is configured to receive a low-side current sense control signal SENSE_PH1_LS. The second input of the AND gate 273 is coupled to the output of the blanking inverter 271. The output of the AND gate 273 is configured to generate a blanked low-side current sense control signal SENSE_PH1_LS_B.

Referring back to FIG. 6, the time duration from t1 to t5 represents one switching period of the first phase. In some embodiments, the low-side current sense control signal SENSE_PH1_LS has a logic high state from t1 to t4, and a logic low state from t4 to t5. PWM_ph2 has a logic high state from t2 to t3, and a logic low state from t1 to t2 and from t3 to t5. According to the operating principle of the blanking circuit 204, the blanked low-side current sense control signal SENSE_PH1_LS_B has a logic high state from t1 to t2 and from t3 to t4, and a logic low state from t2 to t3 and from t4 to t5.

The first phase PWM off time current sense circuit 201 comprises a low-side switch current sense unit 220, a first switch S1, a second switch S2, a third switch S3, an inverter 214 and a delay unit 212. As shown in FIG. 7, the low-side switch current sense unit 220 has a first input IIS1 coupled to Q2D through the first switch S1, a second input IIS2 connected to ground, and an output IOS1 configured to generate a first phase PWM off time current signal.

As shown in FIG. 7, the third switch S3 is connected to the output of the low-side switch current sense unit 220. The blanked low-side current sense control signal SENSE_PH1_LS_B is configured to control the first switch S1 directly, and control the second switch S2 through the inverter 214. The blanked low-side current sense control signal SENSE_PH1_LS_B is also configured to control the third switch S3 through the delay unit 212. The delay unit 212 is configured to add a predetermined delay into the blanked low-side current sense control signal SENSE_PH1_LS_B. The delay unit 212 generates a delayed rising edge signal SENSE_PH1_LS_D. In other words, there is a predetermined delay between the rising edge of SENSE_PH1_LS_B and the rising edge of SENSE_PH1_LS_D. As shown in FIG. 7, the first phase PWM off time current signal generated by the low-side switch current sense unit 220 is fed into a first rebuild capacitor C_{REBUILD1} through the third switch S3.

In operation, the first phase PWM off time current sense circuit 201 is configured to generate the first phase PWM off time current signal proportional to a current flowing through the inductor L1 when the high-side switch Q1 of the first phase is turned off, the high-side switch Q3 of the second phase is turned off, and the low-side switch Q2 of the first phase is turned on. Referring back to FIG. 6, the first phase PWM off time current sense circuit 201 is configured to generate the first portion of the first phase PWM off time current signal (V_{IL1} between t1 and t2) and the third portion of the first phase PWM off time current signal (V_{IL1} between t3 and t4).

The first phase PWM on and off time current rebuild circuit 202 comprises a first voltage-controlled current source VCCS11, a second voltage-controlled current source VCCS12, the first rebuild capacitor C_{REBUILD1}, a fourth switch S4 and a fifth switch S5. As shown in FIG. 7, the first voltage-controlled current source VCCS11, the fourth switch S4, the fifth switch S5 and the second voltage-controlled current source VCCS12 are connected in series between a bias voltage source VDD and ground. The first rebuild capacitor C_{REBUILD1} is connected between a common node of S4 and S5, and ground. The fourth switch S4 is controlled by a first enable signal EN_ITON1. The first enable signal EN_ITON1 is configured such that the fourth switch S4 is turned on when the high-side switch Q1 is turned on. The fifth switch S5 is controlled by a second enable signal EN_ITON2. The second enable signal EN_ITON2 is configured such that the fifth switch S5 is turned on when the high-side switch Q3 is turned on.

In operation, the first phase PWM on and off time current rebuild circuit 202 is configured to construct an artificial inductor current signal using the first voltage-controlled current source VCCS11 to charge the first rebuild capacitor C_{REBUILD1} when the high-side switch Q1 of the phase is turned on. Referring back to FIG. 6, the artificial first phase inductor current signal is the segment of V_{IL1} between t4 and t5.

In operation, the first phase PWM on and off time current rebuild circuit 202 is configured to construct the second portion of the first phase PWM off time current signal using the second voltage-controlled current source VCCS12 to discharge the first rebuild capacitor C_{REBUILD1} when the high-side switch Q3 of the second phase is turned on. Referring back to FIG. 6, the second portion of the first phase PWM off time current signal is the segment of V_{IL1} between t2 and t3.

The first phase feedback loop 203 comprises a track-and-hold circuit 204, a first transconductance amplifier 216 and a first compensation capacitor C_{COMP1}. An input of the track-and-hold circuit 204 is connected to both the first phase PWM off time current sense circuit 201 and the first phase PWM on and off time current rebuild circuit 202. Two inputs of the first transconductance amplifier 216 are connected to two outputs of the track-and-hold circuit 204, respectively. The first compensation capacitor C_{COMP1} is connected to an output of the first transconductance amplifier 216.

As shown in FIG. 7, the track-and-hold circuit 204 comprises a sixth switch S6, a first hold capacitor C_{TH1}, a seventh switch S7 and a second hold capacitor C_{TH2}. The sixth switch S6 and the first hold capacitor C_{TH1} are connected in series between the input of the track-and-hold circuit 204 and ground. A common node of the sixth switch S6 and the first hold capacitor C_{TH1} is connected to a first input of the first transconductance amplifier 216. The seventh switch S7 and the second hold capacitor C_{TH2} are connected in series between the input of the track-and-hold circuit 204 and ground. A common node of the seventh switch S7 and the second hold capacitor C_{TH2} is connected to a second input of the first transconductance amplifier 216.

The first phase feedback loop 203 is capable of constructing the waveform of V_{IL1} between t4 and t5 through adjusting the current generated by the first voltage-controlled current source VCCS11.

In operation, the sixth switch S6 is controlled by a first control signal TH_PH1VTON. The first control signal TH_PH1VTON is configured such that a saved voltage of the artificial first phase inductor current signal is held on the first hold capacitor C_{TH1}. Referring back to FIG. 6, in some embodiments, the saved voltage of the artificial first phase inductor current signal is approximately equal to the voltage of V_{IL1} at t5. The seventh switch S7 is controlled by a second control signal TH_PH1VTOFF. The second control signal TH_PH1VTOFF is configured such that a saved voltage of the first portion of the first phase PWM off time current signal is held on the second hold capacitor C_{TH2}. Referring back to FIG. 6, in some embodiments, the saved voltage of the first portion of the first phase PWM off time current signal is approximately equal to the voltage of the first portion of the first phase PWM off time current signal at t5 or t1 (from t5 to t6, the first phase PWM off time current signal is proportional to ISD_Q2 shown in FIG. 6).

In operation, the first phase feedback loop 203 is configured to adjust a current flowing through the first voltage-controlled current source VCCS11 so as to make the saved voltage of the artificial first phase inductor current signal equal to the saved voltage of the first portion of the first phase PWM off time current signal. Once the saved voltage of the artificial first phase inductor current signal is equal to the saved voltage of the first portion of the first phase PWM off time current signal, the artificial first phase inductor current signal is of a shape similar to that of the current flowing through the high-side switch Q1.

The first phase feedback loop 203 is also capable of constructing the waveform of V_{IL1} between t2 and t3 through adjusting the current generated by the second voltage-controlled current source VCCS12.

In operation, the second control signal TH_PH1VTOFF is configured such that a saved voltage of the second portion of the first phase PWM off time current signal is held on the second hold capacitor C_{TH2}. Referring back to FIG. 6, in some embodiments, the saved voltage of the second portion of the first phase PWM off time current signal is approximately equal to the voltage of V_{IL1} at t3. The first control signal TH_PH1VTON is configured such that a saved voltage of the third portion of the first phase PWM off time current signal is held on the first hold capacitor C_{TH1}. Referring back to FIG. 6, in some embodiments, the saved voltage of the third portion of the first phase PWM off time current signal is approximately equal to the voltage of the third portion of the first phase PWM off time current signal at t3 (from t3 to t4, the first phase PWM off time current signal is proportional to ISD_Q2 shown in FIG. 6).

In operation, the first phase feedback loop 203 is configured to adjust a current flowing through the second voltage-controlled current source VCCS12 so as to make the saved voltage of the second portion of the first phase PWM off time current signal equal to the saved voltage of the third portion of the first phase PWM off time current signal. Once the saved voltage of the second portion of the first phase PWM off time current signal is equal to the saved voltage of the third portion of the first phase PWM off time current signal, the second portion of the first phase PWM off time current signal is of a shape similar to that of the current flowing through the first inductor L1 from t2 to t3.

In some embodiments, the first phase PWM off time current sense circuit 201, the first phase PWM on and off time current rebuild circuit 202 and the first phase feedback loop 203 are configured to generate the first inductor current detection signal V_{IL1} as shown in FIG. 6. The first inductor current detection signal V_{IL1} includes four portions. V_{IL1} from t1 to t2 is formed by sensing a current flowing through the low-side switch Q2 when the low-side switch Q2 is turned on. V_{IL1} from t2 to t3 is generated based on the second portion of the first phase PWM off time current signal. V_{IL1} from t3 to t4 is formed by sensing a current flowing through the low-side switch Q2 when the low-side switch Q2 is turned on. V_{IL1} from t4 to t5 is generated based on the artificial first phase inductor current signal when the high-side switch Q1 is turned on.

It should be noted that depending on design needs, the first inductor current detection signal V_{IL1} may include additional portions. For example, one additional portion of the first inductor current detection signal may be formed by holding a voltage on the first rebuild capacitor during a predetermined blanking time and a settling time at a beginning of an on-time of the low-side switch Q2. Once the blanking time and the settling time have been added, the first inductor current detection signal is of a flat top at the transition around t5.

As shown in FIG. 7, the first inductor current detection signal V_{IL1} is directly tapped at the upper terminal of the first rebuild capacitor C_{REBUILD1}. A second transconductance amplifier 218 is employed to convert the inductor current detection signal V_{IL1} into a corresponding current signal I_{IL1}.

It should be noted that the single-ended current sense apparatus shown in FIG. 7 can be designed in a fully-differential form. More particularly, the low-side switch current sense unit 220 can be implemented as a fully-differential amplifier. The two outputs of the fully-differential amplifier are fed into two rebuild capacitors, two voltage-controlled current sources, two track-and-hold circuits and two transconductance amplifiers. In other words, there are two closely related symmetrical PWM on time current rebuild circuits in a current sense apparatus designed in a fully-differential form.

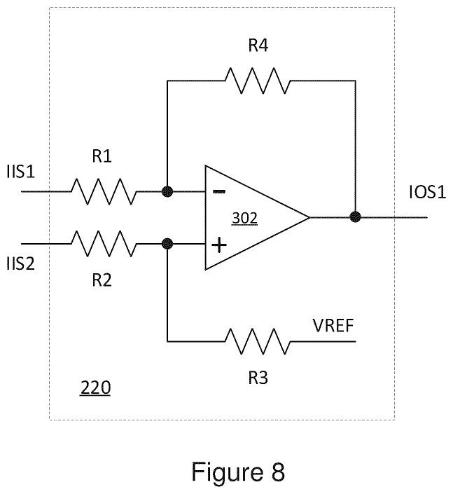

FIG. 8 illustrates a schematic diagram of the low side current sense unit shown in FIG. 7 in accordance with various embodiments of the present disclosure. In some embodiments, the low-side switch current sense unit 220 is implemented as a differential to single-ended amplifier. As shown in FIG. 8, the differential to single-ended amplifier comprises an amplifier 302, a first resistor R1, a second resistor R2, a third resistor R3 and a fourth resistor R4.

The first resistor R1 is connected between the first input IIS1 and an inverting input of the amplifier 302. The second resistor R2 is connected between the second input IIS2 and a non-inverting input of the amplifier 302. The third resistor R3 is connected between the non-inverting input of the amplifier 302 and a predetermined reference VREF. The fourth resistor R4 is connected between the inverting input of the amplifier 302 and the output IOS1 of the amplifier 302.

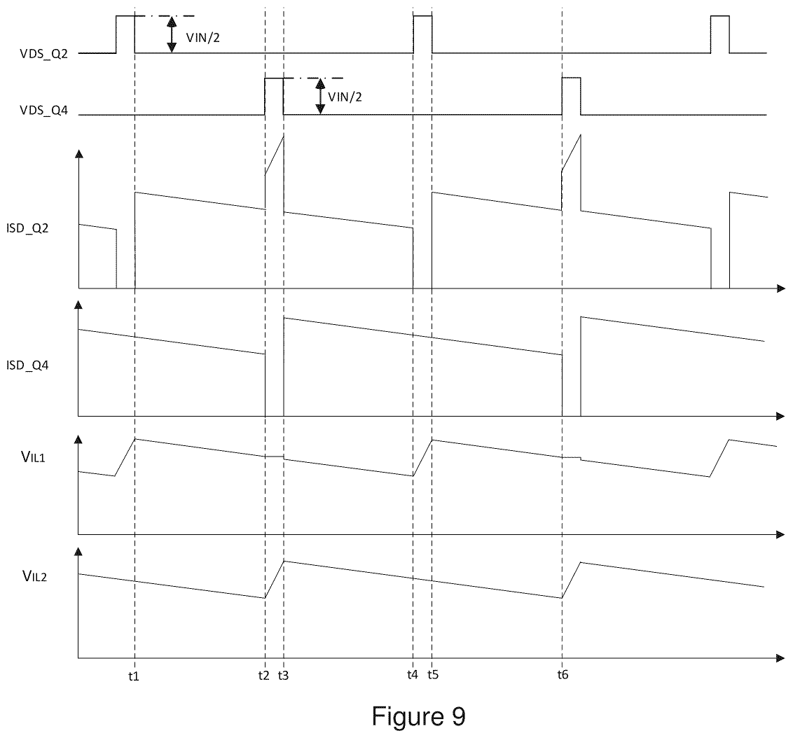

FIG. 9 illustrates various control signals associated with the first current sense apparatus and the second current sense apparatus shown in FIG. 5 in accordance with various embodiments of the present disclosure. The horizontal axis of FIG. 9 represents intervals of time. There are six rows in FIG. 9. The first row represents the drain-to-source voltage of Q2 (VDS_Q2). The second row represents the drain-to-source voltage of Q4 (VDS_Q4). The third row represents the current flowing through Q2 (ISD_Q2). The fourth row represents the current flowing through Q4 (ISD_Q4). The fifth row represents the first inductor current detection signal V_{IL1} generated by the first current sense apparatus 261. The sixth row represents the second inductor current detection signal V_{IL2} generated by the second current sense apparatus 262.

The control signals shown in FIG. 9 are similar to the control signals shown in FIG. 6 except that between t2 and t3, the first inductor current detection signal V_{IL1} (i.e., the voltage on the first rebuild capacitor C_{REBUILD1}) remains constant. This behavior can be achieved either by setting the discharge current (the second voltage-controlled current source VCCS12) to zero during this interval (between t2 and t3), or by excluding the discharge current (the second voltage-controlled current source VCCS12) from the first phase PWM on and off time current rebuild circuit 202.

FIG. 10 illustrates a schematic diagram of the second current sense apparatus shown in FIG. 5 in accordance with various embodiments of the present disclosure. The second current sense apparatus 262 comprises a second phase PWM off time current sense circuit 221, a second phase PWM on time current rebuild circuit 222 and a second phase feedback loop 223 as shown in FIG. 10.

The second phase PWM off time current sense circuit 221 comprises a low-side switch current sense unit 240, an eighth switch S8, a ninth switch S9, a tenth switch S10, an inverter 234 and a delay unit 232. The low-side current sense control signal SENSE_PH2_LS is configured to control the eighth switch S8 directly, and control the ninth switch S9 through the inverter 234. The low-side current sense control signal SENSE_PH2_LS is also configured to control the tenth switch S10 through the delay unit 232. The operating principle of the second phase PWM off time current sense circuit 221 is similar to that of the first phase PWM off time current sense circuit 201 shown in FIG. 7, and hence is not discussed herein to avoid repetition.

The second phase PWM on time current rebuild circuit 222 comprises a second phase voltage-controlled current source VCCS2, a second rebuild capacitor C_{REBUILD2} and an eleventh switch S11. As shown in FIG. 10, the second phase voltage-controlled current source VCCS2, the eleventh switch S11 and the second rebuild capacitor C_{REBUILD2} are connected in series between the bias voltage source VDD and ground. The eleventh switch S11 is controlled by an enable signal EN_ITON. The operating principle of the second phase PWM on time current rebuild circuit 222 is similar to that of the first phase PWM on and off time current rebuild circuit 202 shown in FIG. 7, and hence is not discussed herein to avoid repetition.

The second phase feedback loop 223 comprises a track-and-hold circuit 224, a third transconductance amplifier 236 and a second compensation capacitor C_{COMP2}. The track-and-hold circuit 224 comprises a twelfth switch S12, a third hold capacitor C_{TH3}, a thirteenth switch S13 and a fourth hold capacitor C_{TH4}. The operating principle of the second phase feedback loop 223 is similar to that of the first phase feedback loop 203 shown in FIG. 7, and hence is not discussed herein to avoid repetition.

In some embodiments, the second phase PWM off time current sense circuit 221, the second phase PWM on time current rebuild circuit 222 and the second phase feedback loop 223 are configured to generate a second inductor current detection signal V_{IL2} as shown in FIG. 6. The second inductor current detection signal V_{IL2} includes two portions. V_{IL2} from t3 to t6 is formed by sensing a current flowing through the low-side switch Q4 when the low-side switch Q4 is turned on. V_{IL2} from t2 to t3 is generated based on the artificial second phase inductor current signal when the high-side switch Q3 is turned on.

It should be noted that depending on design needs, the second inductor current detection signal V_{IL2} may include additional portions. For example, one additional portion of the second inductor current detection signal may be formed by holding a voltage on the second rebuild capacitor during a blanking time and a settling time at a beginning of an on-time of the low-side switch Q4. Once the blanking time and the settling time have been added, the second inductor current detection signal is of a flat top during the transition at t3.

As shown in FIG. 10, the second inductor current detection signal V_{IL2} is directly tapped at the upper terminal of the second rebuild capacitor C_{REBUILD2}. A fourth transconductance amplifier 238 is employed to convert the inductor current detection signal V_{IL2} into a corresponding current signal I_{IL2}.

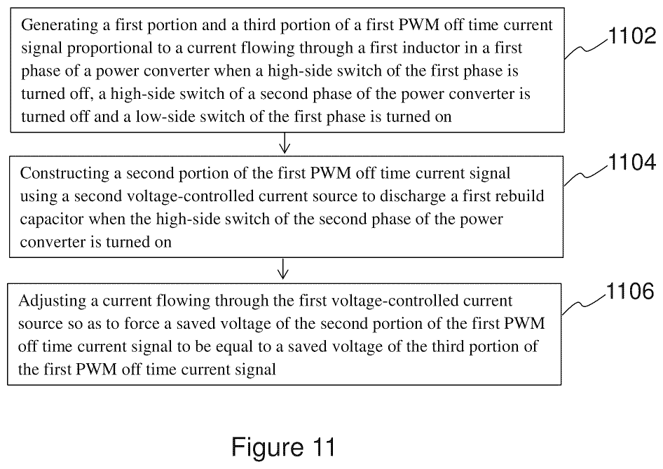

FIG. 11 illustrates a flow chart of a method for sensing the currents flowing through the power converter shown in FIG. 5 in accordance with various embodiments of the present disclosure. This flowchart shown in FIG. 11 is merely an example, which should not unduly limit the scope of the claims. One of ordinary skill in the art would recognize many variations, alternatives, and modifications. For example, various steps illustrated in FIG. 11 may be added, removed, replaced, rearranged and repeated.

At step 1102, a first portion and a third portion of a first PWM off time current signal is generated. The first portion and the third portion of the first PWM off time current signal are proportional to a current flowing through a first inductor in a first phase of a power converter when a high-side switch of the first phase is turned off, a high-side switch of a second phase of the power converter is turned off and a low-side switch of the first phase is turned on.

At step 1104, a second portion of the first PWM off time current signal is constructed using a second voltage-controlled current source to discharge a first rebuild capacitor when the high-side switch of the second phase of the power converter is turned on.

At step 1106, a current flowing through the first voltage-controlled current source is adjusted so as to force a saved voltage of the second portion of the first PWM off time current signal to be equal to a saved voltage of the third portion of the first PWM off time current signal.

The method further comprises constructing a first PWM on time current signal using a first voltage-controlled current source to charge the first rebuild capacitor when the high-side switch in the first phase of the power converter is turned on, and adjusting a current flowing through the first voltage-controlled current source so as to force a saved voltage of the first PWM on time current signal to be equal to a saved voltage of the first portion of the first PWM off time current signal.

The method further comprises generating a second PWM off time current signal proportional to a current flowing through a second inductor in a second phase of the power converter when a high-side switch of the second phase is turned off and a low-side switch of the second phase is turned on, constructing a second PWM on time current signal using a second phase voltage-controlled current source to charge a second rebuild capacitor when the high-side switch of the second phase of the power converter is turned on, and adjusting a current flowing through the second phase voltage-controlled current source so as to force a saved voltage of the second PWM on time current signal to be equal to a saved voltage of the second PWM off time current signal.

The method further comprises upon detecting that the saved voltage of the second portion of the first PWM off time current signal is higher than the saved voltage of the third portion of the first PWM off time current signal, adjusting the second voltage-controlled current source to decrease the saved voltage of the second portion of the first PWM off time current signal until the saved voltage of the second portion of the first PWM off time current signal is equal to the saved voltage of the third portion of the first PWM off time current signal, and upon detecting that the saved voltage of the second portion of the first PWM off time current signal is lower than the saved voltage of the third portion of the first PWM off time current signal, adjusting the second voltage-controlled current source to increase the saved voltage of the second portion of the first PWM off time current signal until the saved voltage of the second portion of the first PWM off time current signal is equal to the saved voltage of the third portion of the first PWM off time current signal.

The method further comprises configuring the second voltage-controlled current source to be connected to the first rebuild capacitor through a controllable switch, and in response to an enable signal, configuring the controllable switch to be turned on when the high-side switch of the second phase of the power converter is turned on.

In some embodiments, the second portion of the first PWM off time current signal is located between the first portion and the third portion of the first PWM off time current signal, and wherein the first portion, the second portion and the third portion of the first PWM off time current signal are concatenated in sequence to construct the first PWM off time current signal.

In some embodiments, the first phase of the power converter comprises the high-side switch of the first phase, a capacitor and the first inductor connected in series between an input voltage bus and an output voltage bus, and the low-side switch of the first phase connected between a common node of the capacitor and the first inductor, and ground, and the second phase of the power converter comprises the high-side switch of the second phase and a second inductor connected in series between a common node of the high-side switch of the first phase and the capacitor, and the output voltage bus, and the low-side switch of the second phase connected between a common node of the high-side switch of the second phase and the second inductor, and ground.

In accordance with an embodiment, a current sense device comprises a second phase PWM off time current sense circuit configured to generate a second phase PWM off time current signal proportional to a current flowing through a second inductor in a second phase of a power converter when a high-side switch of the second phase of the power converter is turned off and a low-side switch of the second phase of the power converter is turned on, a second phase PWM on time current rebuild circuit configured to construct an artificial second phase inductor current signal using a second phase voltage-controlled current source to charge a second rebuild capacitor when the high-side switch of the second phase of the power converter is turned on, and a second phase feedback loop configured to adjust a current flowing through the second phase voltage-controlled current source so as to force a saved voltage of the artificial second phase inductor current signal to be equal to a saved voltage of the second phase PWM off time current signal.

In accordance with another embodiment, a method comprises generating a first portion and a third portion of a first PWM off time current signal proportional to a current flowing through a first inductor in a first phase of a power converter when a high-side switch of the first phase is turned off, a high-side switch of a second phase of the power converter is turned off and a low-side switch of the first phase is turned on, constructing a second portion of the first PWM off time current signal using a first voltage-controlled current source to discharge a first rebuild capacitor when a high-side switch of a second phase of the power converter is turned on, and adjusting a current flowing through the first voltage-controlled current source so as to force a saved voltage of the second portion of the first PWM off time current signal to be equal to a saved voltage of the third portion of the first PWM off time current signal.

In accordance with yet another embodiment, a power conversion system comprises a first phase comprising a high-side switch of the first phase, a capacitor and a first inductor connected in series between an input voltage bus and an output voltage bus, and a low-side switch of the first phase connected between a common node of the capacitor and the first inductor, and ground, a second phase comprising a high-side switch of the second phase and a second inductor connected in series between a common node of the high-side switch of the first phase and the capacitor, and the output voltage bus, and a low-side switch of the second phase connected between a common node of the high-side switch of the second phase and the second inductor, and ground, and a current sense device comprising a first current sense apparatus and a second current sense apparatus, wherein the first current sense apparatus comprises a first phase PWM off time current sense circuit, a first phase PWM on and off time current rebuild circuit and a first phase feedback loop, and the second current sense apparatus comprises a second phase PWM off time current sense circuit, a second phase PWM on time current rebuild circuit and a second phase feedback loop.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above-described embodiment, method, and examples, but by all embodiments and methods within the scope and spirit of the invention as claimed.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A current sense device comprising:
a second phase PWM off time current sense circuit configured to generate a second phase PWM off time current signal proportional to a current flowing through a second inductor in a second phase of a power converter when a high-side switch of the second phase of the power converter is turned off and a low-side switch of the second phase of the power converter is turned on;
a second phase PWM on time current rebuild circuit configured to construct an artificial second phase inductor current signal using a second phase voltage-controlled current source to charge a second rebuild capacitor when the high-side switch of the second phase of the power converter is turned on; and
a second phase feedback loop configured to adjust a current flowing through the second phase voltage-controlled current source so as to force a saved voltage of the artificial second phase inductor current signal to be equal to a saved voltage of the second phase PWM off time current signal.

2. The current sense device of claim 1, further comprising:
a first phase PWM off time current sense circuit configured to generate a first portion and a third portion of a first phase PWM off time current signal proportional to a current flowing through a first inductor in a first phase of the power converter when the high-side switch of the second phase of the power converter is turned off, and a low-side switch of the first phase of the power converter is turned on;
a first phase PWM on and off time current rebuild circuit configured to construct a second portion of the first phase PWM off time current signal using a second voltage-controlled current source to discharge a first rebuild capacitor when the high-side switch of the second phase of the power converter is turned on, and construct an artificial first phase inductor current signal using a first voltage-controlled current source to charge the first rebuild capacitor when a high-side switch of the first phase of the power converter is turned on; and
a first phase feedback loop configured to adjust a current flowing through the second voltage-controlled current source so as to force a saved voltage of the second portion of the first phase PWM off time current signal to be equal to a saved voltage of the third portion of the first phase PWM off time current signal, and adjust a current flowing through the first voltage-controlled current source so as to force a saved voltage of the artificial first phase inductor current signal to be equal to a saved voltage of the first portion of the first phase PWM off time current signal.

3. The current sense device of claim 2, wherein:
the first phase of the power converter comprises:
the high-side switch of the first phase, a capacitor and the first inductor connected in series between an input voltage bus and an output voltage bus, and the low-side switch of the first phase connected between a common node of the capacitor and the first inductor, and ground; and
the second phase of the power converter comprises:
the high-side switch of the second phase and a second inductor connected in series between a common node of the high-side switch of the first phase and the capacitor, and the output voltage bus, and the low-side switch of the second phase connected between a common node of the high-side switch of the second phase and the second inductor, and ground.

4. The current sense device of claim 3, wherein the first phase PWM off time current sense circuit further comprises a first switch, a second switch, a third switch, an inverter, a delay unit and a low-side switch current sense unit, and wherein:
the first switch is connected between the common node of the high-side switch and the low-side switch of the first phase, and a first input of the low-side switch current sense unit;
the second switch is connected between the first input and a second input of the low-side switch current sense unit;
the third switch is connected to an output of the low-side switch current sense unit, wherein the first phase PWM off time current signal is fed into the first rebuild capacitor through the third switch;
a blanked low-side current sense control signal is configured to control the first switch directly and control the second switch through the inverter; and
the blanked low-side current sense control signal is configured to control the third switch through the delay unit.

5. The current sense device of claim 4, wherein:
the blanked low-side current sense control signal is generated by a blanking circuit comprising:
an AND gate having a first input configured to receive a low-side current sense control signal and an output configured to generate the blanked low-side current sense control signal; and
a blanking inverter having an input configured to receive a gate drive signal of the high-side switch of the second phase, and an output coupled to a second input of the AND gate.

6. The current sense device of claim 4, wherein:
the low-side switch current sense unit is a differential to single-ended amplifier.

7. The current sense device of claim 3, wherein:
the first phase PWM on and off time current rebuild circuit comprises the first voltage-controlled current source, the second voltage-controlled current source, the first rebuild capacitor, a fourth switch and a fifth switch, and wherein:
the first voltage-controlled current source is connected to the first rebuild capacitor through the fourth switch;
the second voltage-controlled current source is connected to the first rebuild capacitor through the fifth switch;
the fourth switch is controlled by a first enable signal, and wherein the fourth switch is configured to be turned on when the high-side switch of the first phase is turned on; and
the fifth switch is controlled by a second enable signal, and wherein the fourth switch is configured to be turned on when the high-side switch of the second phase is turned on.

8. The current sense device of claim 3, wherein:
the first feedback loop comprises a track-and-hold circuit, a transconductance amplifier and a compensation capacitor, and wherein:
an input of the track-and-hold circuit is connected to both the first phase PWM off time current sense circuit and the first phase PWM on and off time current rebuild circuit;
two inputs of the transconductance amplifier are connected to two outputs of the track-and-hold circuit, respectively; and
the compensation capacitor is connected to an output of the transconductance amplifier, and wherein the track-and-hold circuit comprises a sixth switch, a first hold capacitor, a seventh switch and a second hold capacitor, and wherein:
the sixth switch and the first hold capacitor are connected in series between the input of the track-and-hold circuit and ground, and wherein a common node of the sixth switch and the first hold capacitor is connected to a first input of the transconductance amplifier; and
the seventh switch and the second hold capacitor are connected in series between the input of the track-and-hold circuit and ground, and wherein a common node of the seventh switch and the second hold capacitor is connected to a second input of the transconductance amplifier.

9. The current sense device of claim 8, wherein:
an output of the transconductance amplifier is coupled to the first voltage-controlled current source and the second voltage-controlled current source.

10. The current sense device of claim 9, wherein the output of the transconductance amplifier is adjusted such that:
the saved voltage of the second portion of the first phase PWM off time current signal is equal to the saved voltage of the third portion of the first phase PWM off time current signal; and
the saved voltage of the artificial second phase inductor current signal is equal to the saved voltage of the first portion of the first phase PWM off time current signal.

11. A method comprising:
generating a first portion and a third portion of a first PWM off time current signal proportional to a current flowing through a first inductor in a first phase of a power converter when a high-side switch of the first phase is turned off, a high-side switch of a second phase of the power converter is turned off and a low-side switch of the first phase is turned on;
constructing a second portion of the first PWM off time current signal using a second voltage-controlled current source to discharge a first rebuild capacitor when the high-side switch of the second phase of the power converter is turned on; and
adjusting a current flowing through the first voltage-controlled current source so as to force a saved voltage of the second portion of the first PWM off time current signal to be equal to a saved voltage of the third portion of the first PWM off time current signal.

12. The method of claim 11, further comprising:
constructing a first PWM on time current signal using a first voltage-controlled current source to charge the first rebuild capacitor when the high-side switch in the first phase of the power converter is turned on; and
adjusting a current flowing through the first voltage-controlled current source so as to force a saved voltage of the first PWM on time current signal to be equal to a saved voltage of the first portion of the first PWM off time current signal.

13. The method of claim 11, further comprising:
generating a second PWM off time current signal proportional to a current flowing through a second inductor in a second phase of the power converter when a high-side switch of the second phase is turned off and a low-side switch of the second phase is turned on;
constructing a second PWM on time current signal using a second phase voltage-controlled current source to charge a second rebuild capacitor when the high-side switch of the second phase of the power converter is turned on; and
adjusting a current flowing through the second phase voltage-controlled current source so as to force a saved voltage of the second PWM on time current signal to be equal to a saved voltage of the second PWM off time current signal.

14. The method of claim 11, further comprising:
upon detecting that the saved voltage of the second portion of the first PWM off time current signal is higher than the saved voltage of the third portion of the first PWM off time current signal, adjusting the second voltage-controlled current source to decrease the saved voltage of the second portion of the first PWM off time current signal until the saved voltage of the second portion of the first PWM off time current signal is equal to the saved voltage of the third portion of the first PWM off time current signal; and
upon detecting that the saved voltage of the second portion of the first PWM off time current signal is lower than the saved voltage of the third portion of the first PWM off time current signal, adjusting the second voltage-controlled current source to increase the saved voltage of the second portion of the first PWM off time current signal until the saved voltage of the second portion of the first PWM off time current signal is equal to the saved voltage of the third portion of the first PWM off time current signal.

15. The method of claim 11, further comprising:
configuring the second voltage-controlled current source to be connected to the first rebuild capacitor through a controllable switch; and
in response to an enable signal, configuring the controllable switch to be turned on when the high-side switch of the second phase of the power converter is turned on.

16. The method of claim 11, wherein:
the second portion of the first PWM off time current signal is located between the first portion and the third portion of the first PWM off time current signal, and wherein the first portion, the second portion and the third portion of the first PWM off time current signal are concatenated in sequence to construct the first PWM off time current signal.

17. The method of claim 11, wherein:
the first phase of the power converter comprises:
the high-side switch of the first phase, a capacitor and the first inductor connected in series between an input voltage bus and an output voltage bus, and the low-side switch of the first phase connected between a common node of the capacitor and the first inductor, and ground; and
the second phase of the power converter comprises:
the high-side switch of the second phase and a second inductor connected in series between a common node of the high-side switch of the first phase and the capacitor, and the output voltage bus, and the low-side switch of the second phase connected between a common node of the high-side switch of the second phase and the second inductor, and ground.

18. A power conversion system comprising:
a first phase comprising:
a high-side switch of the first phase, a capacitor and a first inductor connected in series between an input voltage bus and an output voltage bus, and a low-side switch of the first phase connected between a common node of the capacitor and the first inductor, and ground;
a second phase comprising:
a high-side switch of the second phase and a second inductor connected in series between a common node of the high-side switch of the first phase and the capacitor, and the output voltage bus, and a low-side switch of the second phase connected between a common node of the high-side switch of the second phase and the second inductor, and ground; and
a current sense device comprising a first current sense apparatus and a second current sense apparatus, wherein:
the first current sense apparatus comprises a first phase PWM off time current sense circuit, a first phase PWM on and off time current rebuild circuit and a first phase feedback loop; and
the second current sense apparatus comprises a second phase PWM off time current sense circuit, a second phase PWM on time current rebuild circuit and a second phase feedback loop.

19. The power conversion system of claim 18, wherein:
the second phase PWM off time current sense circuit is configured to generate a second phase PWM off time current signal proportional to a current flowing through the second inductor in the second phase when the high-side switch of the second phase of the power converter is turned off and the low-side switch of the second phase of the power converter is turned on;
the second phase PWM on time current rebuild circuit is configured to construct an artificial second phase inductor current signal using a second phase voltage-controlled current source to charge a second rebuild capacitor when the high-side switch of the second phase of the power converter is turned on; and
the second phase feedback loop is configured to adjust a current flowing through the second phase voltage-controlled current source so as to force a saved voltage of the artificial second phase inductor current signal to be equal to a saved voltage of the second phase PWM off time current signal.

20. The power conversion system of claim 18, wherein:
the first phase PWM off time current sense circuit is configured to generate a first portion and a third portion of a first phase PWM off time current signal proportional to a current flowing through the first inductor in the first phase when the high-side switch of the second phase of the power converter is turned off, the high-side switch of the second phase of the power converter is turned off and the low-side switch of the first phase of the power converter is turned on;
the first phase PWM on and off time current rebuild circuit is configured to construct a second portion of the first phase PWM off time current signal using a second voltage-controlled current source to discharge a first rebuild capacitor when the high-side switch of the second phase of the power converter is turned on, and construct an artificial first phase inductor current signal using a first voltage-controlled current source to charge the first rebuild capacitor when the high-side switch of the first phase of the power converter is turned on; and
the first phase feedback loop is configured to adjust a current flowing through the second voltage-controlled current source so as to force a saved voltage of the second portion of the first phase PWM off time current signal to be equal to a saved voltage of the third portion of the first phase PWM off time current signal, and adjust a current flowing through the first voltage-controlled current source so as to force a saved voltage of the artificial second phase inductor current signal to be equal to a saved voltage of the first portion of the first phase PWM off time current signal.
